(19) United States
(12) Patent Application Publication
(10) Pub. No.: US 2026/0160958 A1
(43) Pub. Date: Jun. 11, 2026

(54) HYBRID-BONDED FACE-TO-BACK PHOTONIC ARCHITECTURE

(71) Applicant: Lightmatter, Inc., Boston, MA (US)

(72) Inventors: Omkar Karhade, Chandler, AZ (US); Sufi Ahmed, Chandler, AZ (US)

(73) Assignee: Lightmatter, Inc., Boston, MA (US)

(21) Appl. No.: 19/413,172

(22) Filed: Dec. 9, 2025

Related U.S. Application Data
(60) Provisional application No. 63/730,193, filed on Dec. 10, 2024.

(51) Int. Cl. G02B 6/42; H10W 90/00; H10W 90/26

(52) U.S. Cl. CPC G02B 6/4213; G02B 6/4206; G02B 6/4214; G02B 6/4239; G02B 6/4245; H10W 90/26; H10W 90/792

(57) ABSTRACT

Described herein are techniques for light extraction in hybrid-bonded photonics packages, in which application-specific integrated circuits (ASICs) are attached to a photonic integrated circuit (PIC) via hybrid-bonding. The techniques developed by the inventors involve extraction of light from the backside of the PIC, as opposed to the top side or the edge of the PIC as in conventional devices. A photonic device comprises a substrate, a PIC, an ASIC and an optical assembly. The PIC is disposed on the substrate and has a first surface and a second surface. The first surface faces the substrate. The ASIC is hybrid-bonded to the second surface of the PIC. The optical assembly comprises a fiber array unit and an optical fiber. The optical assembly is disposed in an opening formed in the substrate and the optical assembly is configured to receive light through the first surface of the PIC.

### CROSS-REFFERENCE TO RELATED APPLICATION

This application claims the benefit of U.S. Provisional Application Ser. No. 63/730,193, filed on Dec. 10, 2024, under Attorney Docket No. L 0858.70109US00 and entitled “HYBRID-BONDED FACE-TO-BACK PHOTONIC ARCHITECTURE,” which is hereby incorporated herein by reference in its entirety.

### BACKGROUND

Photonic integrated circuits (PICs) are devices that integrate multiple photonic components, such as waveguides, detectors, switches and modulators, on a single substrate. Similar to how electronic integrated circuits manipulate electrical signals, PICs manipulate light to transmit, process and detect information at high speeds and with low power consumption.

PICs are increasingly used in applications such as optical communications, data centers, sensing and quantum computing. Integration of photonic components on a common platform enables compact size, reduced cost, improved performance, and enhanced scalability.

### BRIEF SUMMARY

In some aspects, the techniques described herein relate to a photonic device, including: a substrate; a photonic integrated circuit (PIC) disposed on the substrate, the PIC having a first surface and a second surface, wherein the first surface faces the substrate; an application-specific integrated circuit (ASIC) hybrid-bonded to the second surface of the PIC; and an optical assembly including a fiber array unit (FAU) and an optical fiber, wherein the optical assembly is disposed in an opening formed in the substrate and wherein the optical assembly is configured to receive light through the first surface of the PIC.

In some aspects, the techniques described herein relate to a photonic device, wherein the PIC includes a grating coupler configured to emit light towards the first surface of the PIC and wherein the optical assembly is configured to receive the light emitted by the grating coupler.

In some aspects, the techniques described herein relate to a photonic device, wherein the grating coupler is configured to emit the light at an angle relative to an axis that is perpendicular to the first surface of the PIC.

In some aspects, the techniques described herein relate to a photonic device, wherein the FAU is oriented parallel to the first surface of the PIC, and wherein the FAU includes a mirror configured to steer the light emitted by the grating coupler towards the optical fiber.

In some aspects, the techniques described herein relate to a photonic device, further including an underfill disposed between the PIC and the substrate, wherein the underfill defines a cut-out portion in correspondence with the opening formed in the substrate.

In some aspects, the techniques described herein relate to a photonic device, wherein the PIC overhangs a side of the substrate, and the opening is near to the side of the substrate.

In some aspects, the techniques described herein relate to a photonic device, wherein the opening is enclosed within the substrate.

In some aspects, the techniques described herein relate to a photonic device, wherein the PIC includes a waveguide configured to emit light from an edge of the PIC, and wherein the photonic device further includes an edge coupler near the edge of the PIC, the edge coupler including a first mirror configured to steer the light emitted by the waveguide towards the FAU.

In some aspects, the techniques described herein relate to a photonic device, wherein the FAU includes a second mirror configured to steer the light reflected from the first mirror towards the optical fiber.

In some aspects, the techniques described herein relate to a photonic device, wherein the edge coupler is within a recess formed in the PIC.

In some aspects, the techniques described herein relate to a photonic device, wherein the edge coupler further extends in a recess formed in the ASIC.

In some aspects, the techniques described herein relate to a photonic device, further including a capping structure on top of the ASIC, wherein the edge coupler further extends in a recess formed in the capping structure.

In some aspects, the techniques described herein relate to a method for manufacturing a photonic device, the method including: grinding a photonic integrated circuit (PIC); forming an electronic-photonic assembly by attaching an application-specific integrated circuit (ASIC) to the ground PIC using hybrid bonding; attaching the electronic-photonic assembly to a substrate such that a portion of the ground PIC overhangs a side of the substrate; and placing an optical assembly including a fiber array unit (FAU) and an optical fiber in an opening formed in the substrate.

In some aspects, the techniques described herein relate to a method, further including: forming an underfill between the substrate and the electronic-photonic assembly; and etching the underfill to define a cut-out portion in correspondence with the opening formed in the substrate.

In some aspects, the techniques described herein relate to a method, further including singulating the electronic-photonic assembly prior to attaching the electronic-photonic assembly to the substrate.

In some aspects, the techniques described herein relate to a method, further including: forming a recess in the PIC prior to attaching the electronic-photonic assembly to the substrate; and placing an edge coupler in the recess.

In some aspects, the techniques described herein relate to a method, further including singulating the electronic-photonic assembly prior to attaching the electronic-photonic assembly to the substrate and subsequent to placing the edge coupler in the recess.

In some aspects, the techniques described herein relate to a method, wherein singulating the electronic-photonic assembly is performed through the recess.

In some aspects, the techniques described herein relate to a method, wherein the edge coupler includes a first mirror configured to steer light emitted by a waveguide of the PIC towards the FAU.

In some aspects, the techniques described herein relate to a method, wherein the FAU includes a second mirror configured to steer the light reflected from the first mirror towards the optical fiber.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1A is a cross sectional side view of a package with a photonic integrated circuit (PIC) hybrid-bonded to an application-specific integrated circuit (ASIC), in accordance with some embodiments.

FIG. 1B illustrates an implementation of the package of FIG. 1A in which the PIC overhangs a side of the substrate, in accordance with some embodiments.

FIG. 1C illustrates an alternative implementation of the package of FIG. 1A in which the substrate defines an enclosed opening, in accordance with some embodiments.

FIG. 2 is a cross sectional side view of another package with a PIC hybrid-bonded to an ASIC, in accordance with some embodiments.

FIGS. 3A-3L are cross sectional views illustrating a process for fabricating a package, in accordance with some embodiments. In the fabrication step corresponding to FIG. 3A, a PIC base is attached to a temporary carrier. In the fabrication step corresponding to FIG. 3B, the substrate of the base PIC is ground. In the fabrication step corresponding to FIG. 3C, conductive pads are formed on the ground surface of the base PIC. In the fabrication step corresponding to FIG. 3D, ASICs are attached to the base PIC. In the fabrication step corresponding to FIG. 3E, a capping structure is attached to the ASICs. In the fabrication step corresponding to FIG. 3F, the temporary carrier is removed. In the fabrication step corresponding to FIG. 3G, backside bumps are created. In the fabrication step corresponding to FIG. 3H, individual PICs are singulated. FIG. 3I illustrates a PIC following the singulation step. In the fabrication step corresponding to FIG. 3J, a PIC is attached to a substrate. In the fabrication step corresponding to FIG. 3K, an underfill is created between the PIC and the substrate. In the fabrication step corresponding to FIG. 3L, a fiber array unit (FAU) is placed in the opening of the substrate.

FIG. 4A is a cross sectional side view of a package with a PIC hybrid-bonded to an ASIC and including an edge coupler, in accordance with some embodiments.

FIG. 4B illustrates a portion of the package of FIG. 4A, in accordance with some embodiments.

FIG. 5 is a cross sectional side view of another package with a PIC hybrid-bonded to an ASIC and including an edge coupler, in accordance with some embodiments.

FIG. 6 is a cross sectional side view of yet another package with a PIC hybrid-bonded to an ASIC and including an edge coupler, in accordance with some embodiments.

FIG. 7 is a cross sectional side view of yet another package with a PIC hybrid-bonded to an ASIC and including an edge coupler, in accordance with some embodiments.

FIGS. 8A-8M are cross sectional views illustrating a process for fabricating a package, in accordance with some embodiments. In the fabrication step corresponding to FIG. 8A, base PIC is attached to a temporary carrier. In the fabrication step corresponding to FIG. 8B, the substrate of the base PIC is ground. In the fabrication step corresponding to FIG. 8C, conductive pads are formed on the ground surface of the base PIC. In the fabrication step corresponding to FIG. 8D, ASICs are attached to the base PIC. In the fabrication step corresponding to FIG. 8E, a capping structure is attached to the ASICs. In the fabrication step corresponding to FIG. 8F, the temporary carrier is removed. In the fabrication step corresponding to FIG. 8G, recesses are formed in the base PIC. In the fabrication step corresponding to FIG. 8H, backside bumps are created. In the fabrication step corresponding to FIG. 8I, edge couplers are disposed in the recesses. In the fabrication step corresponding to FIG. 8J, individual PICs are singulated. In the fabrication step corresponding to FIG. 8K, a PIC is attached to a substrate. In the fabrication step corresponding to FIG. 8L, a fiber array unit (FAU) is placed in the opening of the substrate.

### DETAILED DESCRIPTION

Described herein are techniques for extraction of light in hybrid-bonded photonics packages, in which application-specific integrated circuits (ASICs) are attached to a photonic integrated circuit (PIC) via hybrid-bonding. Hybrid bonding is a manufacturing technique used to join two semiconductor substrates that is based in part on chemical bonding and in part on mechanical interlocking. Conductive pads formed on the surface of an ASIC come in direct electrical contact with conductive pads formed on the surface of the PIC, without having to resort to solder joints, bumps or other types of connections between the substrates. Eliminating solder joints or bumps allows for a much finer pad pitch (e.g., between 1 μm and 10 μm), which in turn enables a significant increase in the device's bandwidth density.

The inventors have recognized and appreciated that achieving high-volume manufacturing of hybrid-bonded, packaged photonics presents significant challenges. Although existing hybrid-bonding processes can be effective for chip-on-wafer integration in certain high-volume applications, they impose substantial constraints on the types of optical couplers that can be used. For example, conventional couplers such as V-grooves are generally incompatible due to process limitations. In addition, the die-stacking approach typically employed in these processes leaves the PIC edges fully obstructed, making extraction of optical signals difficult.

To address these limitations, the inventors have developed new packages and fabrication methods that overcome at least some of the shortcomings of conventional techniques and enable efficient integration of photonics and electronics through hybrid-bonding. The techniques developed by the inventors and described herein involve extraction of light from the bottom surface of the PIC, as opposed to the top surface or the edge of the PIC as in conventional devices.

Back side coupling can be achieved by placing a fiber in an opening formed through the substrate hosting the PIC-ASIC assembly. The fiber is positioned and oriented to collect light emitted by the PIC in a downward direction. Downward optical emission, in turn, can be achieved using grating couplers, mirrors, or other types of optical steering mechanisms. In some embodiments, the opening can be obtained by removing a portion of the substrate, whether near the edge of the substrate or closer to the mid-portion of the substrate. Removing a portion of the substrate creates a channel in which one or more fibers can be positioned, thereby establishing an optical extraction path. Alternatively, the opening can be created more simply by positioning the PIC-ASIC assembly to overhang the side of the substrate, thereby establishing an optical extraction path next to the substrate.

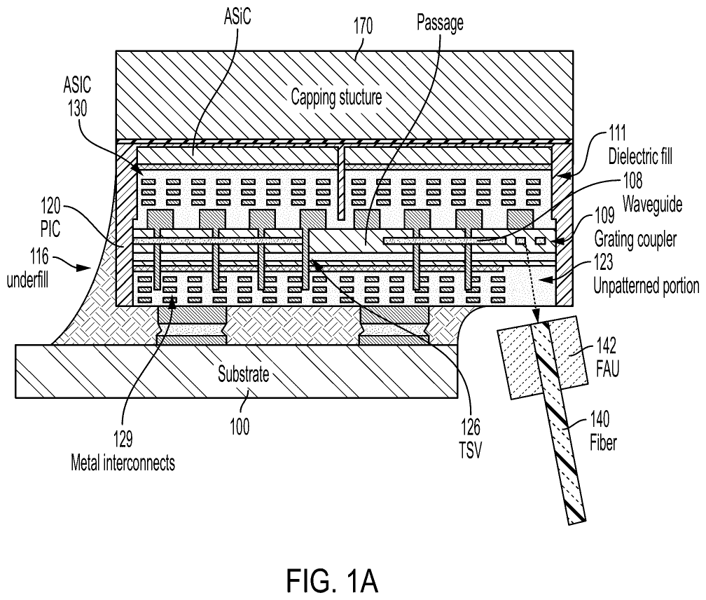

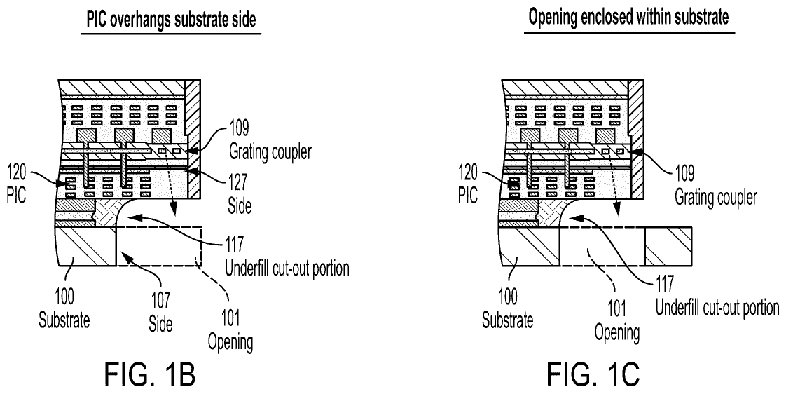

FIG. 1A is a cross sectional side view of a package with a photonic integrated circuit (PIC) hybrid-bonded to application-specific integrated circuits (ASICs), in accordance with some embodiments. The package of FIG. 1A includes a substrate 100. Substrate 100 may be a printed circuit board (PCB) or an organic substrate, for example. Substrate 100 is configured to route signals generated inside the package to external devices and vice versa. A PIC 120 is disposed on substrate 100, whether directly as shown in FIG. 1A or through an intervening component such as an interposer. PIC 120 may be active in nature in that it may include modulators, photodetectors and/or optical switches. In one example, PIC 120 may be equipped with optical switches to route data to (and from) other PICs disposed on the substrate. PIC 120 may further include a network of waveguides 108. In some embodiments, PIC 120 is made of silicon and PIC waveguide 108 may be made of silicon or silicon nitride.

A waveguide 108 is coupled to a grating coupler 109, which is configured to couple light into and out of the PIC. Grating coupler 109 is configured to emit light received from waveguide 108 downwardly, in a direction that is perpendicular to the plane of the PIC or at an angle relative to the axis perpendicular to the plane of the PIC (as shown in FIG. 1A). Additionally, grating coupler 109 is further configured to couple, into waveguide 108, light received at an angle relative to the axis perpendicular to the plane of the PIC or from a direction that is perpendicular to the plane of the PIC.

PIC 120 further includes metal interconnects 129, which include several levels of metal traces interconnected to one another by vias (e.g., tungsten vias). Metal interconnects 129 distribute electrical signals internally within the PIC. The orientation of PIC 120 on substrate 100 may be flipped; as such, metal interconnects 129 are between waveguides 108 and substrate 100. An underfill 116 fills the gap between PIC 120 and substrate 100. Underfill 116 may be made of epoxy or a capillary underfill (CUF).

PIC 120 supports one or more ASICs 130. In the arrangements of FIG. 1A, a pair of ASICs is disposed on PIC 120, although any other suitable number of ASICs per PIC may be used. A plurality of through-silicon vias (TSVs) 126 is patterned within PIC 120 and place the electronic circuitry of PIC 120 in electrical communication with ASICs 130. Each ASIC may include input/output (I/O) circuitry, processing circuitry and/or memory circuitry. The I/O circuitry may include serializers/deserializers (SerDes), for example. The processing circuitry may be implemented as a central processing unit (CPU), a graphics processing unit (GPU), a field programmable gate array (FPGA), a tensor processing unit (TPU), an accelerator, etc. The memory circuitry may be implemented as a high-bandwidth memory (HBM), for example.

Collectively, the ASICs may form a computer system including multiple I/O chips, processing chips and/or multiple memory chips that are optically interconnected with one another through PICs.

ASICs 130 are attached to PIC 120 via hybrid-bonding. Prior to bonding, the surfaces of the PIC and ASICs are polished to achieve extreme flatness, for example using chemical-mechanical polishing (CMP), to ensure contact between the surfaces without gaps. The surfaces are subsequently brought into direct contact at the molecular level, eliminating the need for an intermediate adhesive or solder material. As such, conductive pads formed on the surface of an ASIC come in direct electrical contact with conductive pads formed on the surface of the PIC, without having to resort to solder bumps or other types of connections between them.

Eliminating solder joints improves signal integrity because solder joints introduce resistive, capacitive, or inductive losses. Additionally, materials commonly used for direct bonding (e.g., copper) have better heat dissipation properties than solder alloys. This represents a significant improvement for PICs operating at high power or in compact designs where thermal management is critical. Lastly, the pad pitch in hybrid-bonded assemblies is substantially smaller than what can be achieved with conventional bump-based bonding techniques. For example, the pitch may be less than 10 μm.

Hybrid bonding in accordance with some embodiments may be performed at wafer scale; an entire electronic wafer that has been pre-patterned with electronic circuitry is hybrid-bonded to an entire photonic wafer that has been pre-patterned with photonic devices. The wafers may be 6″, 9″, 12″, 15″ or 18″ in diameter, for example. Hybrid-bonding in accordance with these embodiments is performed without having to first singulate individual dies. This approach is more desirable than die-die bonding in that it supports high-volume manufacturing, ensuring consistent performance and quality and reducing further handling and processing steps.

The surface of PIC 120 facing substrate 100 is referred to herein as the bottom surface or back surface. By contrast, the surface of PIC 120 attached to ASIC 130 is referred to herein as the top surface.

A capping structure 170 is attached to the top surface of ASICs 130. Capping structure 170 may be made of silicon, for example, although other materials may be used. Capping structure 170 covers the ASICs, protecting the package from external agents. A dielectric fill 111 protects the sides of the electronic-photonic assembly. However, the presence of dielectric fill 111 leaves the edge of PIC 120 fully obstructed, making extraction of optical signals using conventional tapers difficult.

An optical assembly, including a fiber array unit (FAU) 142 and an optical fiber 140 pre-attached to the FAU, is positioned in an opening 101 formed through substrate 100. In one example, an FAU 142 includes an array of V-grooves or U-grooves-V-shaped or U-shaped channels that have been etched on a substrate to hold fibers in place. Opening 101 creates a channel through which light emitted by grating coupler 109 is extracted out of the package, using fiber 140. Opening 101 can be defined in various ways, as illustrated in the alternative implementations of FIG. 1B and FIG. 1C. In these figures, FAU 142 and fiber 140 have been removed to illustrate opening 101 more clearly. In the example of FIG. 1B, opening 101 is defined by positioning PIC 120 to overhang side 107 of substrate 100. In other words, PIC's side 127 is offset relative to substrate's side 107, with PICs'side 127 extending farther outward than substrate's side 107. This arrangement results in an optical extraction path near side 107. A portion of underfill 116 is removed in correspondence with opening 101, for example using etching techniques, to define a cut-out portion 117. Cut-out portion 117 permits passage of light emitted by grating coupler 109.

In the example of FIG. 1C, opening 101 is defined after the electronic-photonic assembly has been attached to the substrate, by removing a portion of substrate 100 (e.g., using etching or grinding techniques). In this implementation, opening 101 is formed near the mid-portion of substrate 100. As such, opening 101 is enclosed within substrate 100. In other implementations, however, opening 101 is formed near the side of substrate 100, thus moving the substrate's edge farther inside the package.

Referring back to FIG. 1A, PIC 120 includes an unpatterned portion underneath grating coupler 109 that is free of metal layers, vias or other features that may otherwise cause scattering as light emitted by grating coupler 109 propagates in the downward direction.

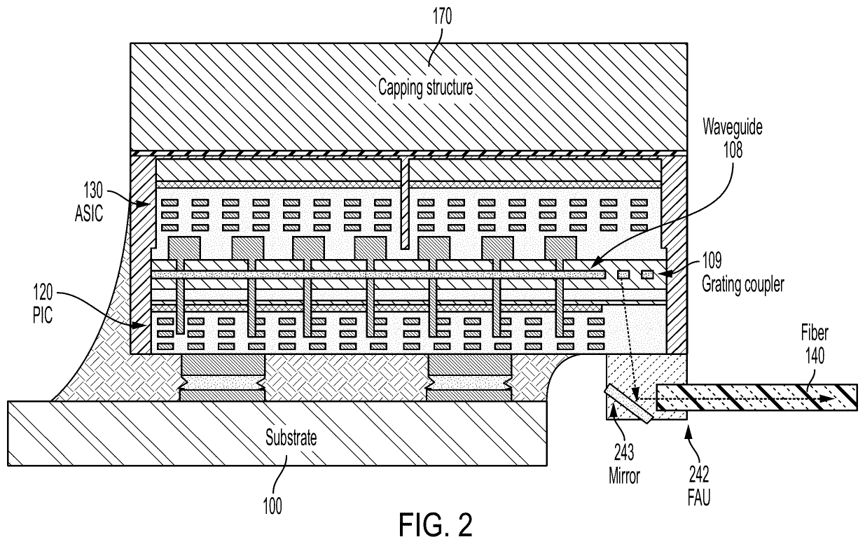

As further shown in FIG. 1A, FAU 142 is oriented at an angle relative to the axis perpendicular to the PIC's bottom surface. The angle may be chosen to match the angle of maximum emission of grating coupler 109. The angle may be, for example, between 0° and 10°. In other implementations, however, FAU 142 may be oriented at about 90° from the axis perpendicular to the PIC's bottom surface. In other words, FAU 142 may be oriented to be parallel to the plane of the PIC. FIG. 2 illustrates an example of this arrangement.

The photonic device of FIG. 2 is similar to the photonic device of FIG. 1A in that PIC 120 emits light using a grating coupler 109, and an FAU placed in an opening of substrate 100 couples the emitted light to a fiber. In this implementation, however, FAU 242 is oriented to be parallel to the plane of the PIC. To steer light emitted by grating coupler 109 into fiber 140, FAU 242 includes a mirror 243.

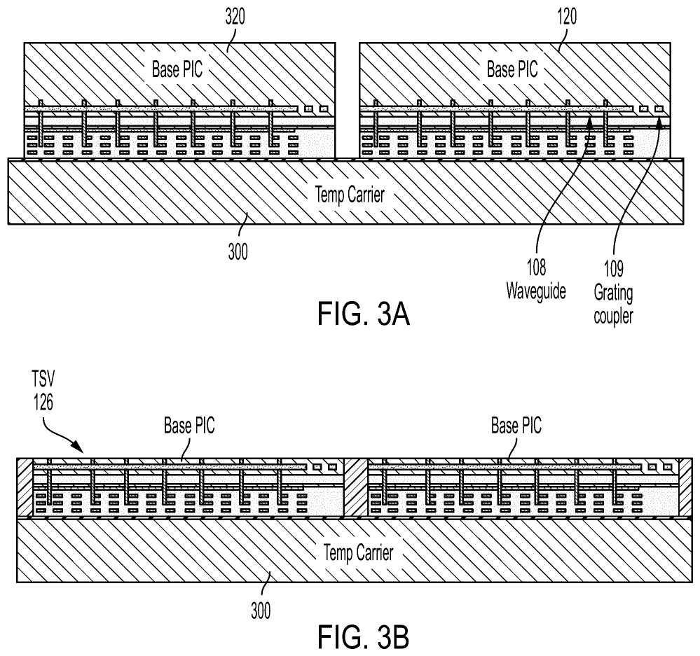

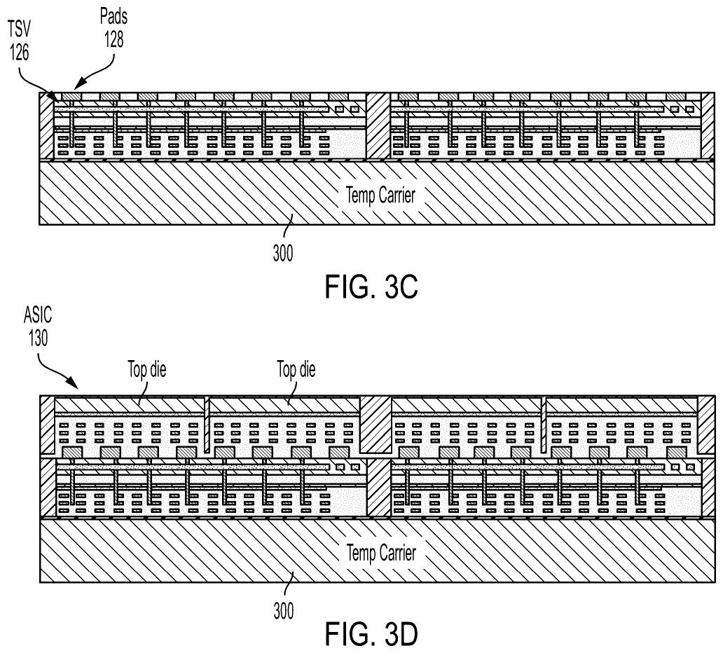

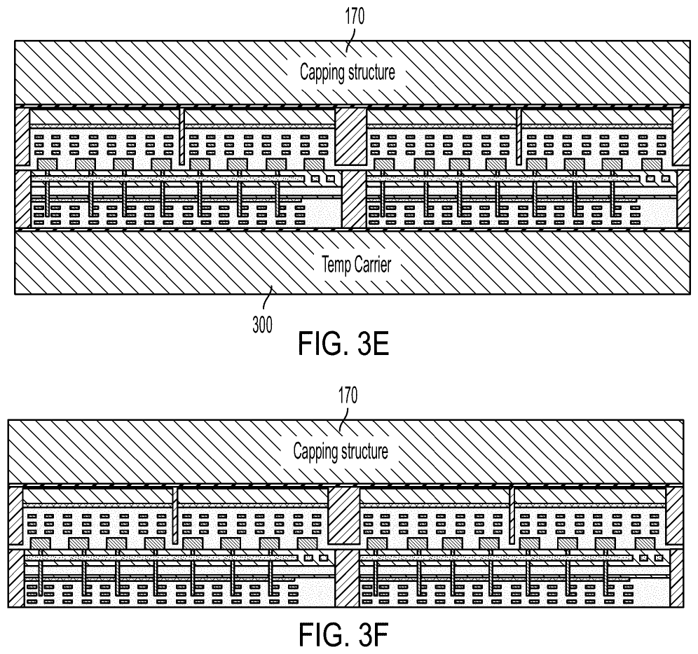

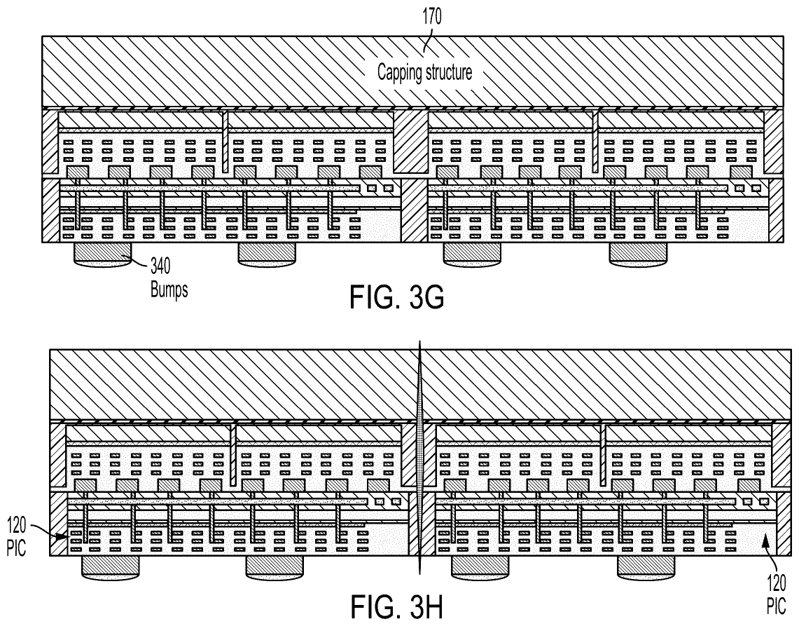

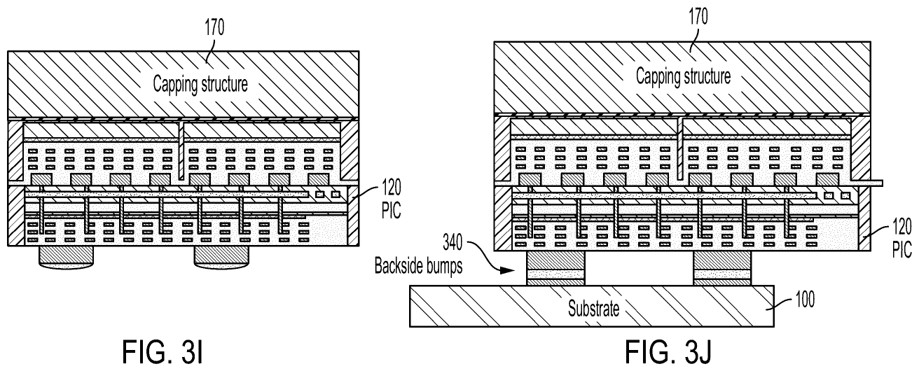

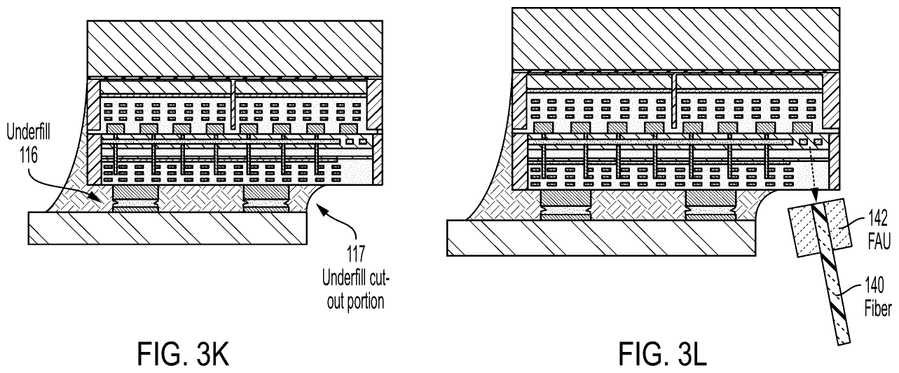

FIGS. 3A-3L are cross sectional views illustrating a process for fabricating the package of FIG. 1A, in accordance with some embodiments. In the fabrication step corresponding to FIG. 3A, a base PIC 320 is attached to a temporary carrier 300. At this stage, base PIC 320 may be part of a wafer patterned with multiple reticle shots. Various photonic components are patterned with base PIC 320, including waveguide 108 and grating coupler 109. In the fabrication step corresponding to FIG. 3B, the silicon substrate of base PIC 320 is ground, thereby exposing TSVs 126. In the fabrication step corresponding to FIG. 3C, conductive pads 128 are formed on the ground surface of base PIC 320 to be in contact with TSVs 126. In some embodiments, the separation between adjacent conductive pads may be less than 10 μm.

In the fabrication step corresponding to FIG. 3D, application-specific integrated circuits (ASICs) 130 are attached to the base PIC using hybrid-bonding. In the fabrication step corresponding to FIG. 3E, a capping structure 170 is attached to the ASICs. In the fabrication step corresponding to FIG. 3F, temporary carrier 300 is removed. In the fabrication step corresponding to FIG. 3G, bumps 340 are created on the bottom surface of base PIC 320. In the fabrication step corresponding to FIG. 3H, individual PICs 120 are singulated from base PIC 320. This step may be performed using a die saw. FIG. 3I illustrates a PIC 120 following the singulation step. In the fabrication step corresponding to FIG. 3J, a PIC 120 is attached to a substrate 100. Bumps 340 electrically connect PIC 120 to substrate 100. The PIC may be positioned to overhang a side of substrate 100, thus creating an optical extraction path through the back side of the package. Alternatively, a portion of substrate 100 may be removed after the PIC has been attached to the substrate, as described above in connection with FIG. 1C. In the fabrication step corresponding to FIG. 3K, an underfill 116 is created between the PIC and the substrate. Subsequently, part of underfill 116 is removed to form a cut-out portion 117. Lastly, in the fabrication step corresponding to FIG. 3L, an optical assembly including a fiber 140 pre-attached to an FAU 142 is placed in the opening of the substrate. As a result, fiber 140 is optically coupled to PIC 120.

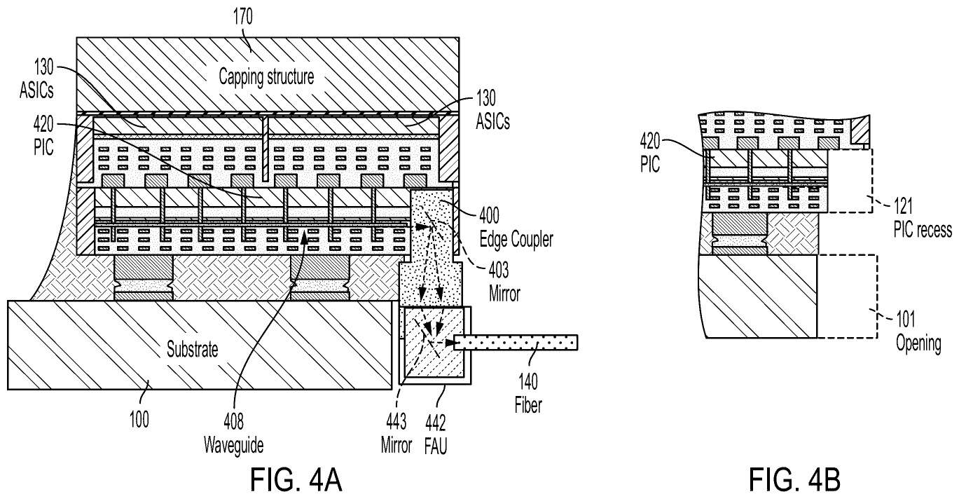

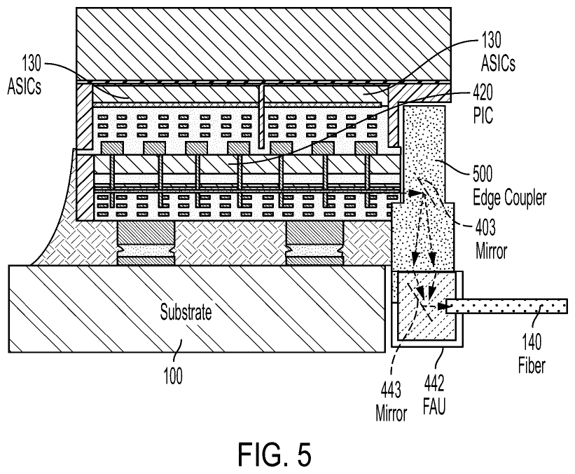

The implementations described above rely on grating couplers to emit light towards the back side of the package. In other implementations, light may be emitted in the lateral direction (along the plane of waveguide 108), and an external edge coupler may be used to steer light towards the back side of the package. FIGS. 4A, 5, 6 and 7 illustrate examples of photonic devices including external edge couplers, in accordance with some embodiments.

Referring first to FIG. 4A, this photonic device includes an edge coupler 400 positioned near an edge of PIC 420. Edge coupler 400 may be made of silicon or glass, for example, and may be patterned with optical components configured to steer light emitted by waveguide 408 towards FAU 422. For example, edge coupler 400 may include a mirror 403. Similar to the examples described in connection with FIG. 1A and FIG. B, FAU 422 is positioned in an opening of substrate 100 to couple light received from PIC 420 into fiber 140. A mirror 443 is formed as part of, or is otherwise attached to, FAU 442. Mirror 443 steers light received from mirror 403 towards fiber 140.

In the example of FIG. 4A, edge coupler 400 is disposed in a recess 121 formed through PIC 420. Recess 121 is shown in FIG. 4B, illustrating the optical coupling portion of the package of FIG. 4A (for clarity, coupler 400 and FAU 442 have been removed from FIG. 4B). As shown, a portion of PIC 420 has been removed, thus forming a recess 121. As a result, ASIC 130 overhangs a side of PIC 420. Edge coupler 400 is positioned to occupy recess 121 and (optionally) part of opening 101.

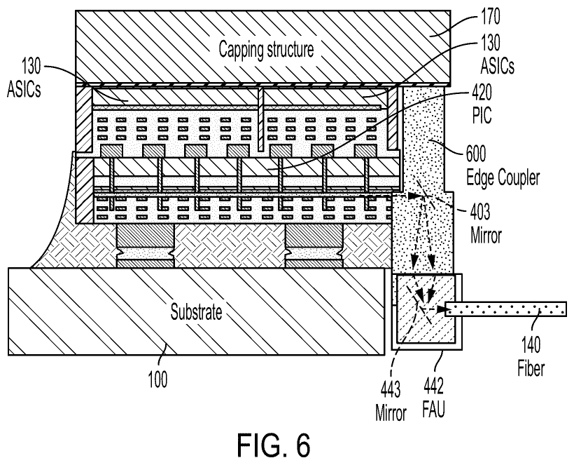

The implementations of FIGS. 5-6 are similar to the implementation of FIG. 4A in that an edge coupler steers light emitted from the PIC towards FAU 442. However, the implementations of FIGS. 5-6 differ from the implementation of FIG. 4A in that the edge coupler extends farther in the upward direction. In FIG. 5, edge coupler 500 extends in a recess formed in ASIC 130. In FIG. 6, edge coupler 600 further extends in a recess formed in capping structure 170. These arrangements increase the contact surface between the edge coupler and the side of the PIC-ASIC assembly, resulting in a stronger and more stable connection.

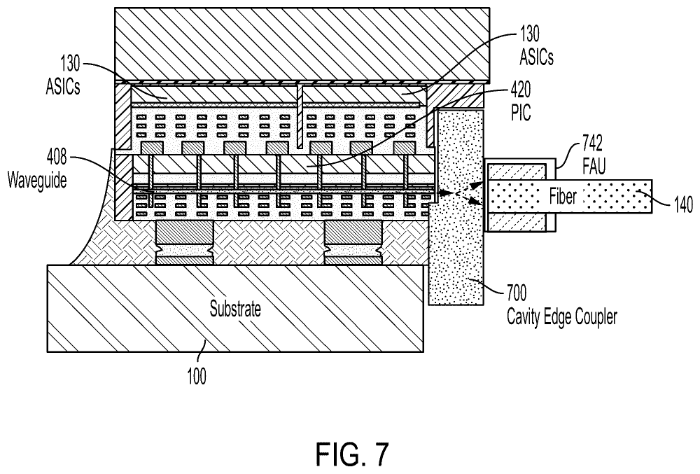

In the implementation of FIG. 7, the FAU lies on the plane of waveguide 408. As shown, edge coupler 700 is interposed between waveguide 408 and FAU 742. Edge coupler 700 occupies the space between PIC 420 and edge coupler 700, thus increasing the local refractive index relative to air. This effect improves the PIC-fiber coupling efficiency. Optionally, edge coupler 700 may act as a lens configured to spatially modulate light emitted by waveguide 408, further improving the coupling efficiency.

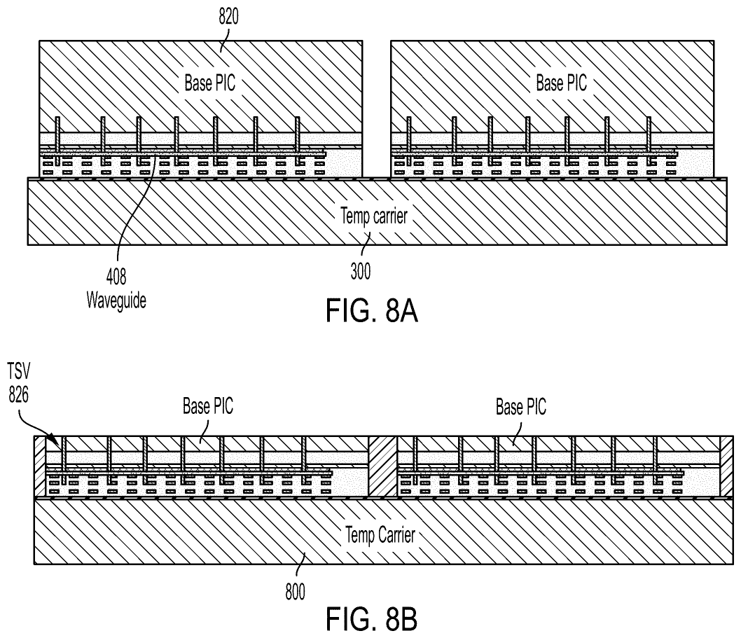

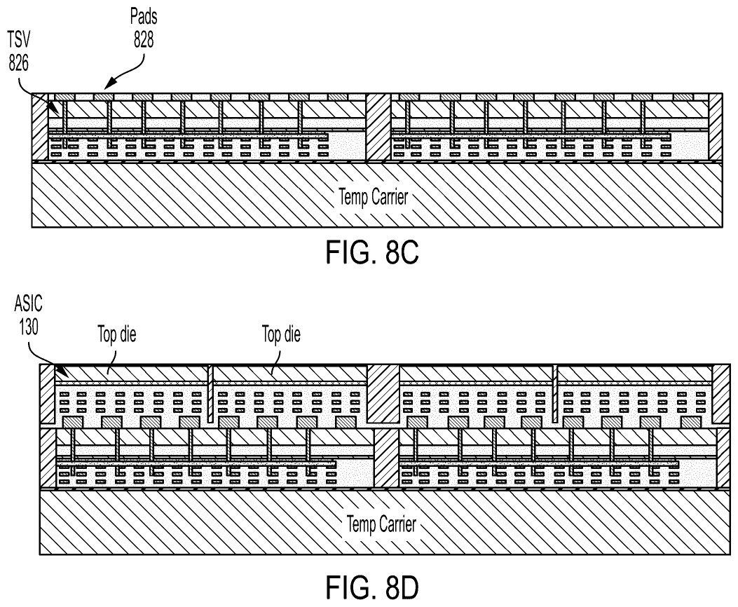

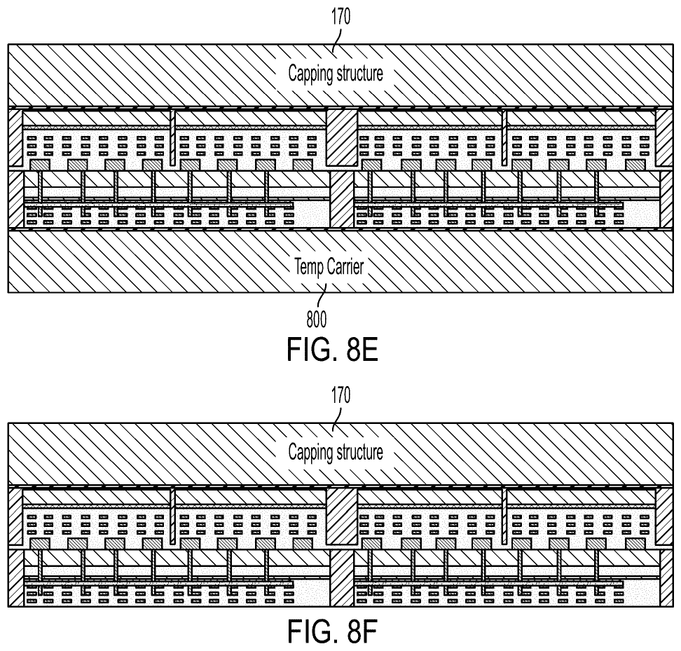

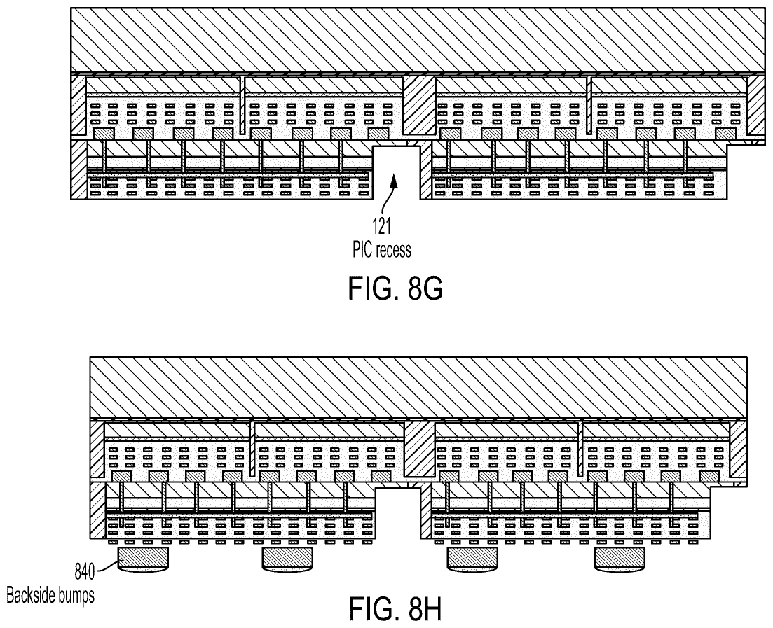

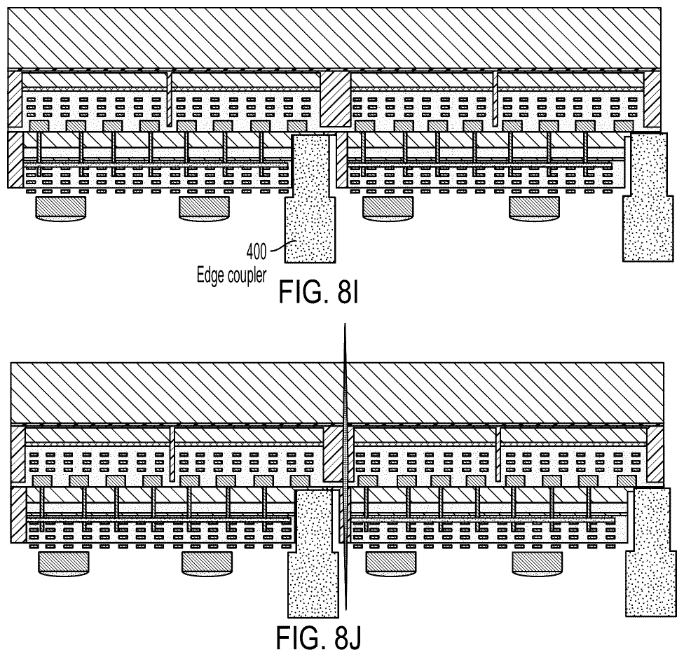

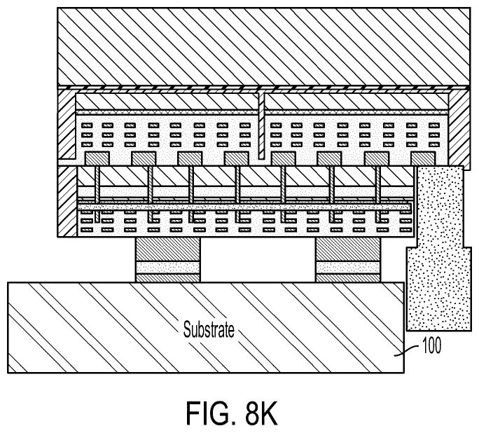

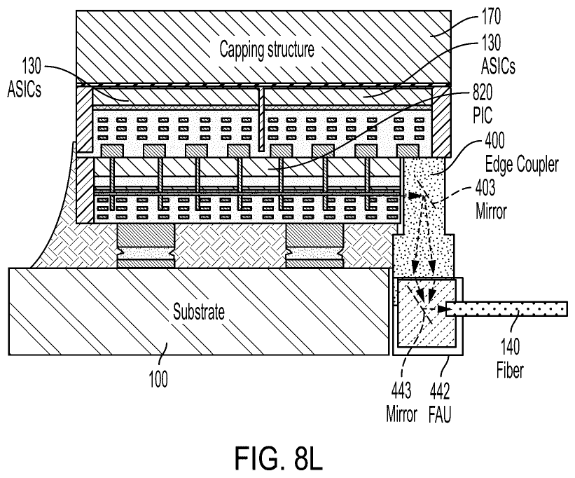

FIGS. 8A-8L are cross sectional views illustrating a process for fabricating the package of FIG. 4A, in accordance with some embodiments. In the fabrication step corresponding to FIG. 8A, a base PIC 820 is attached to a temporary carrier 800. At this stage, base PIC 820 may be part of a wafer patterned with multiple reticle shots. Various photonic components are patterned with base PIC 820, including waveguide 408. In the fabrication step corresponding to FIG. 8B, the silicon substrate of base PIC 820 is ground, thereby exposing TSVs 826. In the fabrication step corresponding to FIG. 8C, conductive pads 828 are formed on the ground surface of base PIC 820 to be in contact with TSVs 826. In the fabrication step corresponding to FIG. 8D, ASICs 130 are attached to the base PIC using hybrid-bonding. In the fabrication step corresponding to FIG. 8E, a capping structure 170 is attached to the ASICs. In the fabrication step corresponding to FIG. 8F, temporary carrier 800 is removed. In the fabrication step corresponding to FIG. 8G, recesses 121 are formed by etching portions of the bottom surface of base PIC 820 near the ends of waveguides 408. In the fabrication step corresponding to FIG. 8H, bumps 840 are created on the bottom surface of base PIC 820. In the fabrication step corresponding to FIG. 8I, edge couplers 400 are disposed in the recesses 121. In the fabrication step corresponding to FIG. 8J, individual PICs 420 are singulated from base PIC 820. This step may be performed using a die saw through recesses 121. In the fabrication step corresponding to FIG. 8K, a PIC 420 is attached to a substrate 100. Bumps 840 electrically connect PIC 420 to substrate 100. The PIC may be positioned to overhang a side of substrate 100, thus creating an optical extraction path through the back side of the package. Alternatively, a portion of substrate 100 may be removed after the PIC has been attached to the substrate. In the fabrication step corresponding to FIG. 8L, an optical assembly including a fiber 140 pre-attached to an FAU 442 is placed in the opening of the substrate. As a result, fiber 140 is optically coupled to PIC 420 via edge coupler 400.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than described, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.” The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

What is claimed is:

1. A photonic device, comprising:
a substrate;
a photonic integrated circuit (PIC) disposed on the substrate, the PIC having a first surface and a second surface, wherein the first surface faces the substrate;
an application-specific integrated circuit (ASIC) hybrid-bonded to the second surface of the PIC; and
an optical assembly comprising a fiber array unit (FAU) and an optical fiber, wherein the optical assembly is disposed in an opening formed in the substrate and wherein the optical assembly is configured to receive light through the first surface of the PIC.

2. The photonic device of claim 1, wherein the PIC comprises a grating coupler configured to emit light towards the first surface of the PIC and wherein the optical assembly is configured to receive the light emitted by the grating coupler.

3. The photonic device of claim 2, wherein the grating coupler is configured to emit the light at an angle relative to an axis that is perpendicular to the first surface of the PIC.

4. The photonic device of claim 2, wherein the FAU is oriented parallel to the first surface of the PIC, and wherein the FAU comprises a mirror configured to steer the light emitted by the grating coupler towards the optical fiber.

5. The photonic device of claim 1, further comprising an underfill disposed between the PIC and the substrate, wherein the underfill defines a cut-out portion in correspondence with the opening formed in the substrate.

6. The photonic device of claim 1, wherein the PIC overhangs a side of the substrate, and the opening is near to the side of the substrate.

7. The photonic device of claim 1, wherein the opening is enclosed within the substrate.

8. The photonic device of claim 1, wherein the PIC comprises a waveguide configured to emit light from an edge of the PIC, and wherein the photonic device further comprises an edge coupler near the edge of the PIC, the edge coupler comprising a first mirror configured to steer the light emitted by the waveguide towards the FAU.

9. The photonic device of claim 8, wherein the FAU comprises a second mirror configured to steer the light reflected from the first mirror towards the optical fiber.

10. The photonic device of claim 8, wherein the edge coupler is within a recess formed in the PIC.

11. The photonic device of claim 10, wherein the edge coupler further extends in a recess formed in the ASIC.

12. The photonic device of claim 11, further comprising a capping structure on top of the ASIC, wherein the edge coupler further extends in a recess formed in the capping structure.

13. A method for manufacturing a photonic device, the method comprising:
grinding a photonic integrated circuit (PIC);
forming an electronic-photonic assembly by attaching an application-specific integrated circuit (ASIC) to the ground PIC using hybrid bonding;
attaching the electronic-photonic assembly to a substrate such that a portion of the ground PIC overhangs a side of the substrate; and
placing an optical assembly comprising a fiber array unit (FAU) and an optical fiber in an opening formed in the substrate.

14. The method of claim 13, further comprising:
forming an underfill between the substrate and the electronic-photonic assembly; and
etching the underfill to define a cut-out portion in correspondence with the opening formed in the substrate.

15. The method of claim 13, further comprising singulating the electronic-photonic assembly prior to attaching the electronic-photonic assembly to the substrate.

16. The method of claim 13, further comprising:
forming a recess in the PIC prior to attaching the electronic-photonic assembly to the substrate; and
placing an edge coupler in the recess.

17. The method of claim 16, further comprising singulating the electronic-photonic assembly prior to attaching the electronic-photonic assembly to the substrate and subsequent to placing the edge coupler in the recess.

18. The method of claim 17, wherein singulating the electronic-photonic assembly is performed through the recess.

19. The method of claim 16, wherein the edge coupler comprises a first mirror configured to steer light emitted by a waveguide of the PIC towards the FAU.

20. The method of claim 19, wherein the FAU comprises a second mirror configured to steer the light reflected from the first mirror towards the optical fiber.
